(19) United States
(12) Patent Application Publication
(10) Pub. No.: US 2025/0120064 A1
(43) Pub. Date: Apr. 10, 2025

(54) SEMICONDUCTOR DEVICE

(71) Applicant: SAMSUNG ELECTRONICS CO., LTD., Suwon-si (KR)

(72) Inventors: Younggeun Song, Suwon-si (KR); Si Nyeon Kim, Suwon-si (KR); Juho Lee, Suwon-si (KR)

(21) Appl. No.: 18/639,633

(22) Filed: Apr. 18, 2024

(30) Foreign Application Priority Data
Oct. 5, 2023 (KR) 10-2023-0132182

(51) Int. Cl. H10B 12/00

(52) U.S. Cl. CPC H10B 12/315; H10B 12/05; H10B 12/482; H10B 12/50

(57) ABSTRACT

A semiconductor device includes a plurality of bit lines BL extending in a first direction D1, and semiconductor patterns SP respectively disposed on the bit lines BL, with each of the semiconductor patterns SP including a first vertical portion V1 and a second vertical portion V2 facing each other in the first direction D1, and a horizontal portion H connecting the first vertical portion V1 and the second vertical portion V2, first and second word lines WL1 and WL2 extending in a second direction D2 across the bit lines BL, and the first and second word lines WL1 and WL2 may be disposed adjacent to the first and second vertical portions V1 and V2 on the horizontal portions H of the semiconductor patterns SP, respectively.

### CROSS-REFERENCE TO RELATED APPLICATIONS

This application claims priority under 35 U.S.C. § 119 to Korean Patent Application No. 10-2023-0132182, filed in the Korean Intellectual Property Office on Oct. 5, 2023, the disclosure of which is incorporated by reference herein in its entirety.

### BACKGROUND OF THE INVENTION

As the design rule of semiconductor devices decrease, manufacturing technology has been developed to improve integration of semiconductor devices and improve operation speed and yield. Accordingly, a transistor with a vertical channel has been proposed to improve the integration, resistance, and current driving ability of the transistor.

### SUMMARY

In general, in some aspects, the present disclosure is directed toward a semiconductor device having improved electrical characteristics and reliability and a method of manufacturing the same.

According to some aspects of the present disclosure, a semiconductor device includes a plurality of bit lines extending in a first direction, semiconductor patterns respectively disposed on the bit lines, and each including a first vertical portion and a second vertical portion facing each other in the first direction, and a horizontal portion connecting the first vertical portion and the second vertical portion, first and second word lines extending in a second direction across the bit lines, and disposed adjacent to the first and second vertical portions on the horizontal portions of the semiconductor patterns, respectively, gate insulating patterns interposed between the first vertical portions and the first word line and between the second vertical portions and the second word line, and extending in the second direction across the bit lines, and first capping patterns interposed between one of the gate insulating patterns and the first vertical portions, and second capping patterns interposed between another one of the gate insulating patterns and the second vertical portions. The first capping patterns may be spaced apart from each other in the second direction with the one of the gate insulating patterns interposed therebetween, and the second capping patterns may be spaced apart from each other in the second direction with the another one of the gate insulating patterns interposed therebetween.

According to some aspects of the present disclosure, a semiconductor device includes a plurality of bit lines extending in a first direction, semiconductor patterns respectively disposed on the bit lines, and each including a first vertical portion and a second vertical portion facing each other in the first direction, first and second word lines extending in a second direction across the bit lines, and disposed on inner surfaces of the first and second vertical portions of the semiconductor patterns, respectively, a gate insulating pattern interposed between the first vertical portions and the first word line and extending in the second direction across the bit lines, and first capping patterns interposed between the gate insulating pattern and the first vertical portions. The first capping patterns may be spaced apart from each other in the second direction with the gate insulating pattern therebetween.

According to some aspects of the present disclosure, a semiconductor device includes peripheral circuit structures on a substrate, an interlayer insulating layer on the peripheral circuit structure, a plurality of bit lines and a plurality of shielding structures extending in a first direction in the interlayer insulating layer, being spaced apart from each other in a second direction, and arranged alternately, semiconductor patterns respectively disposed on the bit lines, and each including a first vertical portion and a second vertical portion facing each other in the first direction, and a horizontal portion connecting the first vertical portion and the second vertical portion, first and second word lines extending in the second direction across the bit lines, and disposed adjacent to the first and second vertical portions on the horizontal portions of the semiconductor patterns, respectively, gate insulating patterns interposed between the first vertical portions and the first word line and between the second vertical portions and the second word line, and extending in the second direction across the bit lines, and first capping patterns interposed between one of the gate insulating patterns and the first vertical portions, and second capping patterns interposed between another one of the gate insulating patterns and the second vertical portions. The first capping patterns may be spaced apart from each other in the second direction with the one of the gate insulating patterns interposed therebetween, and the second capping patterns may be spaced apart from each other in the second direction with the another one of the gate insulating patterns interposed therebetween.

### BRIEF DESCRIPTION OF THE DRAWINGS

Example implementations will be more clearly understood from the following brief description, taken in conjunction with the accompanying drawings.

FIG. 1 is a block diagram of an example of a semiconductor memory device including a semiconductor device according to some implementations.

FIG. 2 is a schematic perspective view of an example of a semiconductor device according to some implementations.

FIG. 3 is a plan view of an example of a semiconductor device according to some implementations.

FIG. 4 is a cross-sectional view corresponding to line A-A′ in FIG. 3 according to some implementations.

FIG. 5 is a cross-sectional view corresponding to line B-B′ in FIG. 3 according to some implementations.

FIG. 6 is a cross-sectional view corresponding to line C-C′ in FIG. 3 according to some implementations.

FIGS. 7A to 7D are cross-sectional views corresponding to line D-D′ in FIG. 3 according to some implementations.

FIGS. 8A to 13D are cross-sectional views illustrating an example of a method of manufacturing the semiconductor device of FIGS. 7A and 7B according to some implementations.

FIG. 14 is a cross-sectional view illustrating an example of a process of manufacturing the semiconductor device of FIGS. 7C and 7D according to some implementations.

### DETAILED DESCRIPTION

Hereinafter, example implementations will be described in detail with reference to the accompanying drawings.

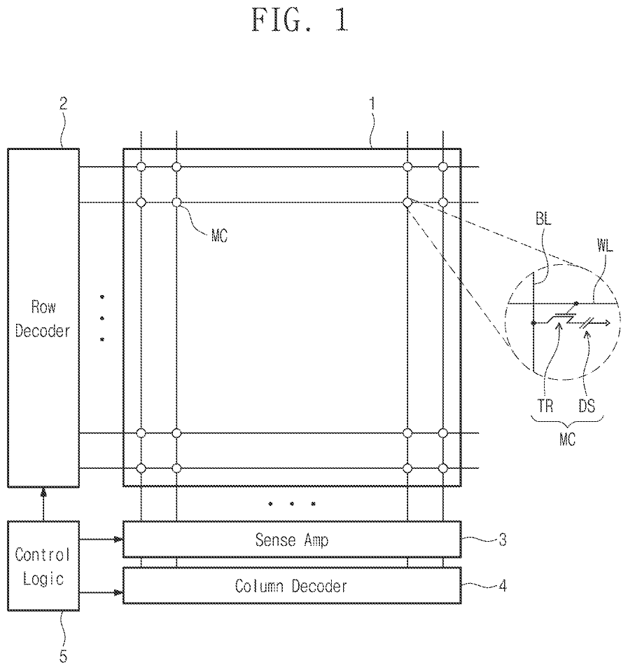

FIG. 1 is a block diagram of an example of a semiconductor memory device including a semiconductor device according to some implementations. In FIG. 1, a semiconductor memory device may include a memory cell array 1, a row decoder 2, a sense amplifier 3, a column decoder 4, and a control logic 5.

The memory cell array 1 may include a plurality of memory cells MC, which are two-dimensionally or three-dimensionally arranged. Each of the memory cells MC may be provided between and connected to a word line WL and a bit line BL, which are disposed to cross each other.

Each of the memory cells MC may include a selection element TR and a data storage element DS, which are electrically connected to each other in series. The selection element TR may be provided between and connected to the data storage element DS and the word line WL, and the data storage element DS may be connected to the bit line BL through the selection element TR. In some implementations, the selection element TR may be a field effect transistor (FET), and the data storage element DS may be realized using at least one of a capacitor, a magnetic tunnel junction pattern, or a variable resistor. For example, the selection element TR may include a transistor whose gate electrode is connected to the word line WL and whose drain/source terminals are connected to the bit line BL and the data storage element DS, respectively.

The row decoder 2 may be configured to decode address information, which is input from the outside, and to select one of the word lines WL of the memory cell array 1, based on the decoded address information. The address information decoded by the row decoder 2 may be provided to a row driver, and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which is selected based on address information decoded by the column decoder 4, and a reference bit line.

The column decoder 4 may be used as a data transmission path between the sense amplifier 3 and an external device (e.g., a memory controller). The column decoder 4 may be configured to decode address information, which is input from the outside, and to select one of the bit lines BL, based on the decoded address information.

The control logic 5 may be configured to generate control signals, which are used to control data-writing or data-reading operations on the memory cell array 1.

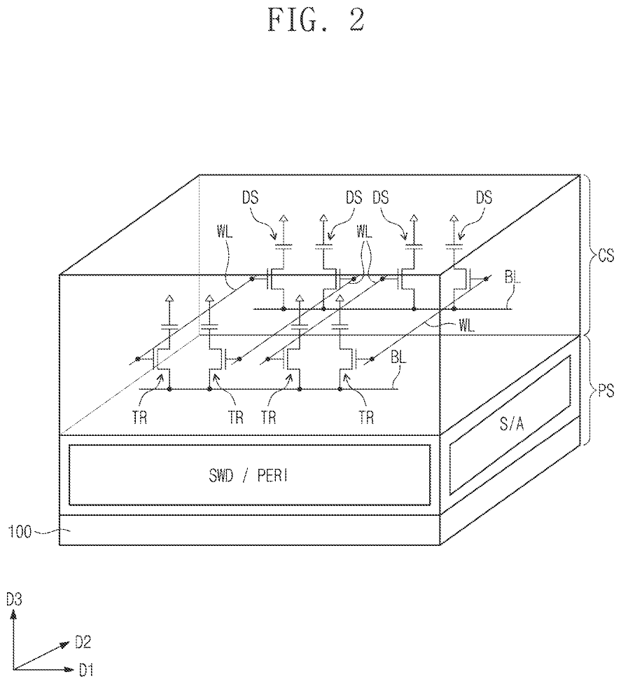

FIG. 2 is a schematic perspective view of an example of a semiconductor device according to some implementations. In FIG. 2, a semiconductor memory device may include a peripheral circuit structure PS on a semiconductor substrate 100 and a cell array structure CS on the peripheral circuit structure PS, according to some embodiment of the inventive concept.

The peripheral circuit structure PS may include core and peripheral circuits, which are formed on the semiconductor substrate 100. The core and peripheral circuits may include the row and column decoders 2 and 4, the sense amplifier 3, and the control logics 5 described with reference to FIG. 1. The peripheral circuit structure PS may be provided between the semiconductor substrate 100 and the cell array structure CS, in a third direction D3 perpendicular to an upper surface of the semiconductor substrate 100.

The cell array structure CS may include the bit lines BL, the word lines WL, and the memory cells MC therebetween (in FIG. 1). The memory cells MC may be two- or three-dimensionally arranged on a plane, which are extended in first and second directions D1 and D2 that are not parallel to each other. Each of the memory cells MC may include the selection element TR and the data storage element DS, as described above.

According to some implementations, a vertical channel transistor (VCT) may be provided as the selection element TR of each memory cell MC. The VCT may include a transistor whose channel region is extended in a direction perpendicular to the upper surface of the semiconductor substrate 100, i.e., in the third direction D3. In addition, a capacitor may be provided as the data storage element DS of each memory cell MC (in FIG. 1).

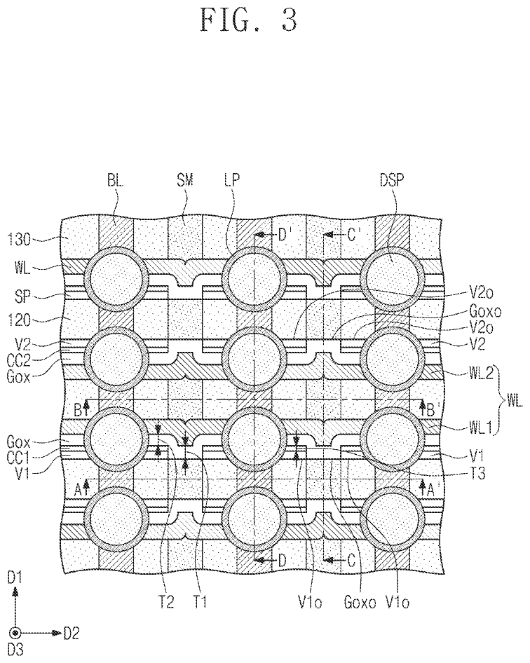

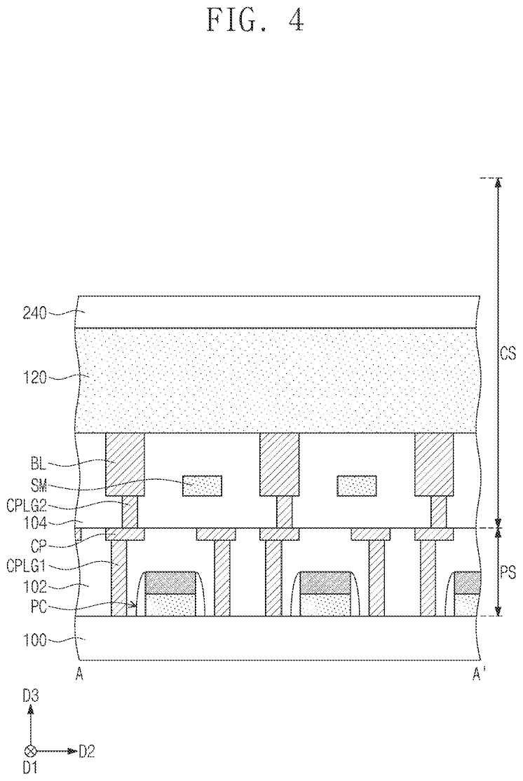

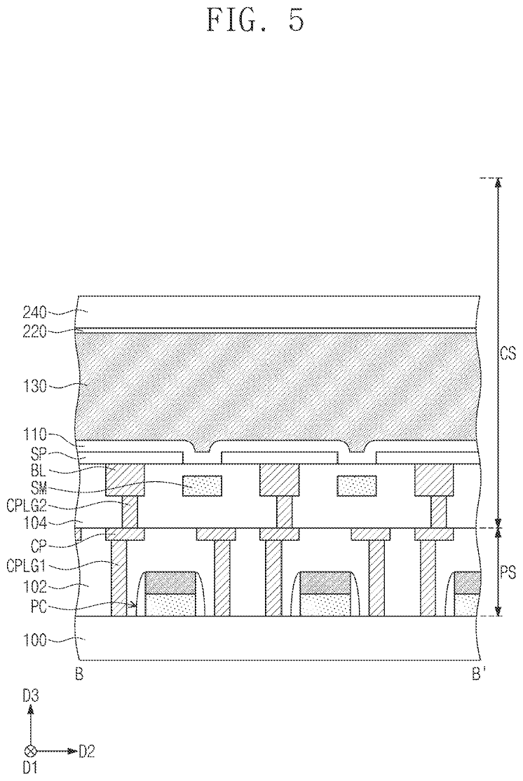

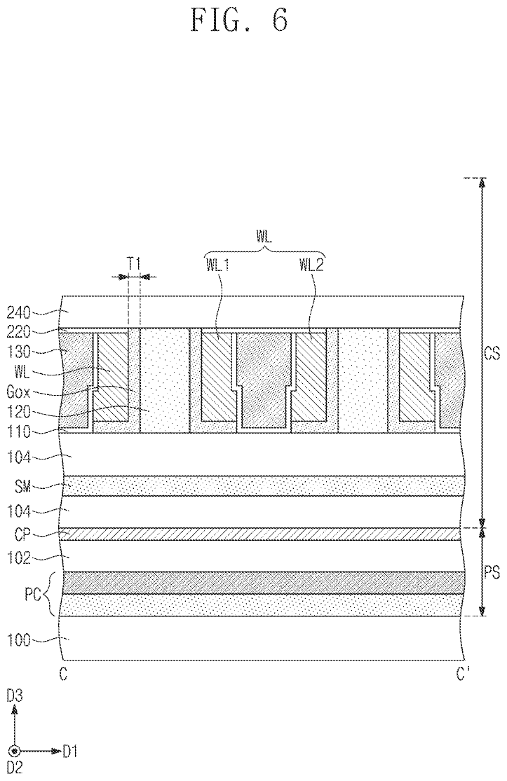

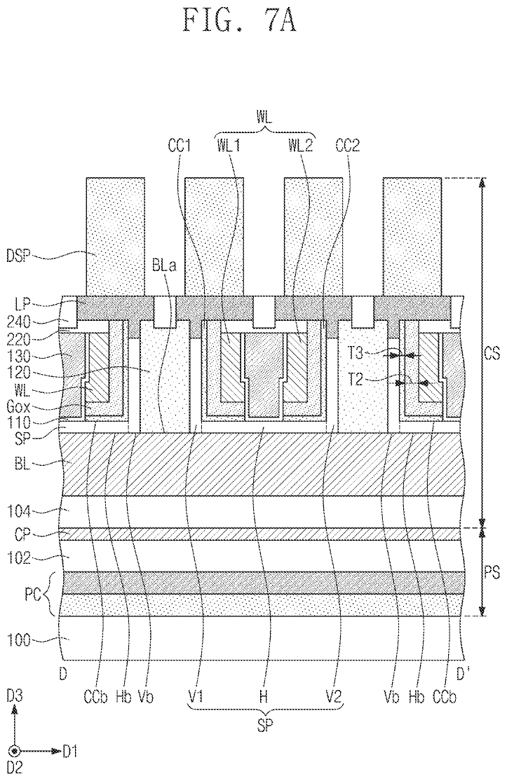

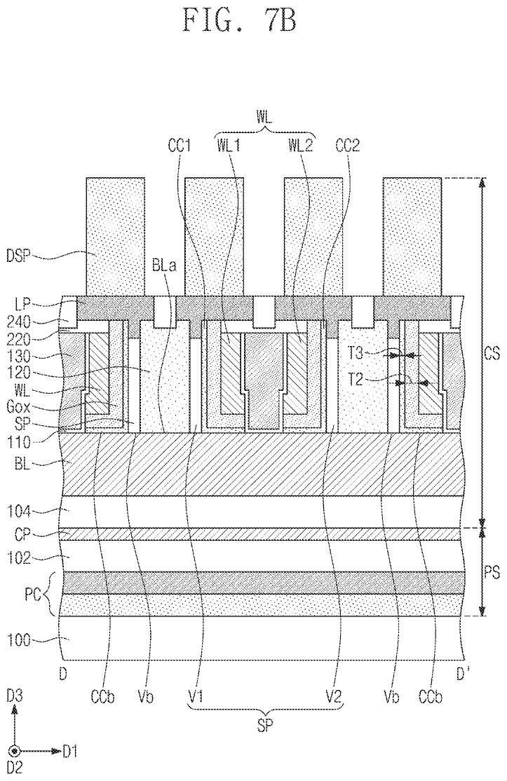

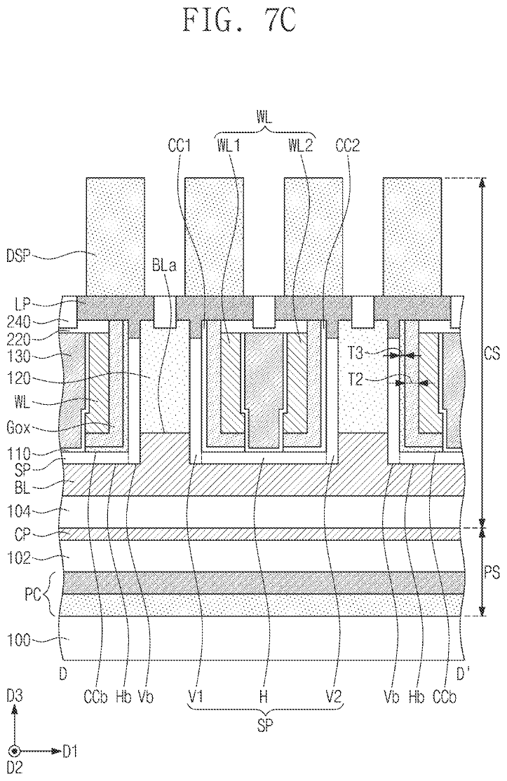

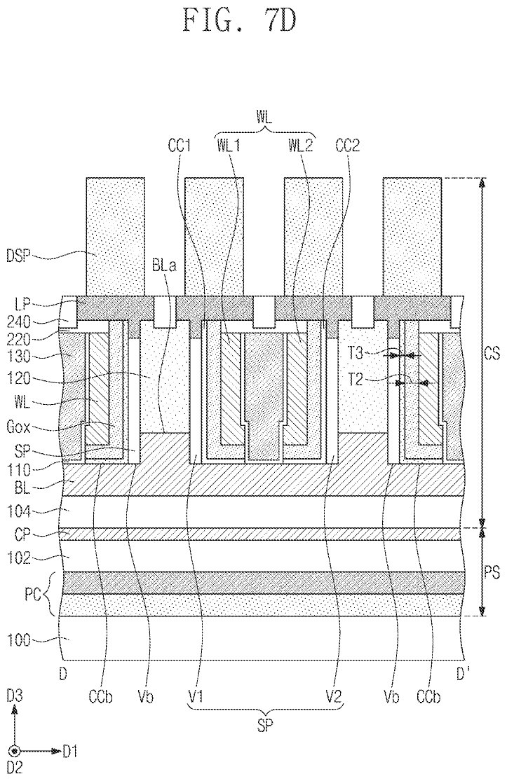

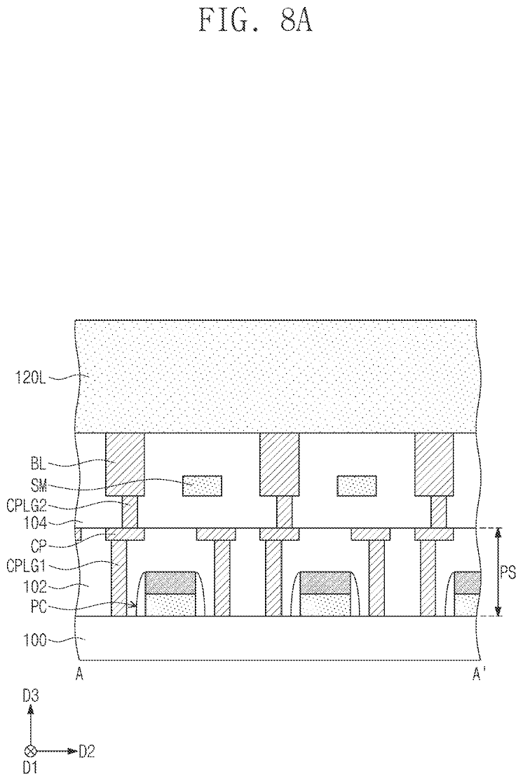

FIG. 3 is a plan view of an example of a semiconductor device according to some implementations. FIG. 4 is a cross-sectional view corresponding to line A-A′ in FIG. 3 according to some implementations. FIG. 5 is a cross-sectional view corresponding to line B-B′ in FIG. 3 according to some implementations. FIG. 6 is a cross-sectional view corresponding to line C-C′ in FIG. 3 according to some implementations. FIG. 7A is a cross-sectional view corresponding to line D-D′ in FIG. 3 according to some implementations.

In FIGS. 3, 4, 5, 6, and 7A, a semiconductor device according to some implementations may include a substrate 100, a peripheral circuit structure PS on the substrate 100, and a cell array structure CS on the peripheral circuit structure PS.

The substrate 100 may be a semiconductor substrate. The substrate 100 may be, for example, a silicon substrate, a germanium substrate, or a silicon-germanium substrate.

The peripheral circuit structure PS may include a peripheral gate structure PC integrated on the substrate 100, peripheral contact pads CP, peripheral contact plugs CPLG1, and a first interlayer insulating layer 102 covering them. In some implementations, the peripheral gate structure PC may include the sense amplifier 3 of FIG. 1.

The cell array structure CS may include memory cells including VCT's. The cell array structure CS may include a plurality of cell contact plugs CPLG2, a plurality of bit lines BL, a plurality of shielding structures SM, a second interlayer insulating layer 104, and a plurality of semiconductor patterns SP, a plurality of word lines WL, a plurality of gate insulating patterns Gox, and data storage patterns DSP. The second interlayer insulating layer 104 may cover the cell contact plugs CPLG2 and the shielding structures SM.

In some implementations, the peripheral gate structures PC of the peripheral circuit structure PS may be electrically connected to the bit lines BL through the peripheral contact plugs CPLG1, peripheral contact pads CP, and cell contact plugs CPLG2. Each of the first and second interlayer insulating layers 102 and 104 may include multi-layered insulating layers and, for example, may include at least one of silicon oxide, silicon nitride, silicon oxynitride, and a low dielectric material. In some implementations, the low dielectric material refers to a material having a lower dielectric constant than silicon oxide. For example, the low dielectric material may include a dielectric material with a dielectric constant of 3.9 or less, and may include a material doped with silicon oxide with fluorine (F) or carbon (C).

A bit line BL may be provided on the substrate 100 in the second interlayer insulating layer 104 and may extend in a first direction D1. A plurality of bit lines BL may be provided, and the bit lines BL may be spaced apart from each other in a second direction D2. The bit line BL may be electrically connected to the peripheral contact pad CP through the cell contact plug CPLG2. The first direction D1 and the second direction D2 may be parallel to an upper surface of the substrate and intersect each other.

The bit line BL may be, for example, doped polysilicon, metal (e.g., Al, Cu, Ti, Ta, Ru, W, Mo, Pt, Ni, Co), conductive metal nitride (e.g., TiN, TaN, WN, NbN, TiAlN, TiSiN, TaSiN, RuTiN), conductive metal silicide or conductive metal oxide (e.g. PtO, RuO₂, IrO₂, SrRuO₃ (SRO), (Ba,Sr)RuO₃ (BSRO), CaRuO₃ (CRO), LSCo), but is not limited thereto. The bit line BL may include a single layer or multiple layers of the above-described materials. In some implementations, the bit line BL may include a two-dimensional semiconductor material, for example, the two-dimensional material may include graphene, carbon nanotubes, or a combination thereof.

The shielding structures SM may be provided between the bit lines BL, respectively, and the shielding structures SM may extend in the first direction D1. The bit lines BL and the shielding structures SM may be spaced apart from each other in the second direction D2 and arranged alternatingly. The shielding structures SM may include, for example, a conductive material, such as metal. The shielding structures SM may be provided in the second interlayer insulating layer 104, and upper surfaces of the shielding structures SM may be positioned at a lower height than uppermost surfaces BLa of the bit lines BL.

In some implementations, the shielding structures SM may be formed of a conductive material and may include an air gap or void therein. For example, air gaps may be provided in the second interlayer insulating layer 104 instead of the shielding structures SM.

The semiconductor pattern SP may be disposed on the bit line BL, and a plurality of semiconductor patterns SP may be provided. The semiconductor patterns SP may be spaced apart from each other in the first and second directions D1 and D2.

The semiconductor pattern SP may include a first vertical portion V1 and a second vertical portion V2 facing each other, and a horizontal portion H connecting the first and second vertical portions V1 and V2. The horizontal portion H may be adjacent to a lower portion of the first and second vertical portions V1 and V2 and connect the first and second vertical portions V1 and V2.

The uppermost surface BLa of the bit line BL may extend in a straight line in the first direction D1. A height of the upper surface of the bit line BL may remain substantially the same in the first direction D1. Accordingly, the upper surface of the bit line BL may be the uppermost surface BLa of the bit line BL, which will be described later.

The horizontal portion H of the semiconductor pattern SP may be provided on the upper surface of the bit line BL. The lower surface Hb of the horizontal portion H may be in contact with the uppermost surface BLa of the bit line BL and may be positioned at substantially the same height as the uppermost surface BLa of the bit line BL.

The horizontal portion H may include a common source/drain region, and upper portions of the first and second vertical portions V1 and V2 may include first and second source/drain regions, respectively. The first vertical portion V1 may include a first channel region between the common source/drain region and the first source/drain region, and the second vertical portion V2 may include a second channel region between the common source/drain region and the second source/drain region. Each of the first and second vertical portions V1 and V2 may be electrically connected to the bit line BL. For example, in some implementations, the semiconductor device may have a structure in which a pair of vertical channel transistors share one bit line BL.

The semiconductor pattern SP may include an oxide semiconductor, and may include at least one of, for example, InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, and InxGayO, but is not limited thereto. For example, the semiconductor pattern SP may include indium gallium zinc oxide (IGZO). The semiconductor pattern SP may include a single layer or multiple layers of an oxide semiconductor. The semiconductor pattern SP may include an amorphous, crystalline, or polycrystalline oxide semiconductor. In some implementations, the semiconductor pattern SP may have a band gap energy greater than that of silicon. For example, the semiconductor pattern SP may have a bandgap energy of about 1.5 eV to 5.6 eV. For example, the semiconductor pattern SP may have optimal channel performance when, the semiconductor pattern SP has a band gap energy of about 2.0 eV to 4.0 eV. For example, the semiconductor pattern SP may be polycrystalline or amorphous, but is not limited thereto. In some implementations, the semiconductor pattern SP may include a two-dimensional semiconductor material, for example, graphene, carbon nanotubes, or a combination thereof.

The word line WL may be disposed between the first vertical portion V1 and the second vertical portion V2. A plurality of word lines WL may be provided. The word lines WL may extend in the second direction D2 and be spaced apart from each other in the first direction D1.

Each of the word lines WL may include a first word line WL1 and a second word line WL2, and the first word line WL1 and the second word line WL2 may face each other in the first direction D1. The first word line WL1 may cover an inner surface of the first vertical portion V1, and the inner surface of the first vertical portion V1 may be one side surface of the first vertical portion V1 facing a second vertical portion V2. The first and second word lines WL1 and WL2 may be disposed adjacent to the first and second vertical portions V1 and V2, respectively, on the horizontal portions H of the semiconductor patterns SP.

The first word line WL1 may be adjacent to the first channel region of the first vertical portion V1 and may control the first channel region. The second word line WL2 may cover an inner surface of the second vertical portion V2, and an inner surface of the second vertical portion V2 may be one side surface of the second vertical portion V2 facing the first vertical portion V1. The second word line WL2 may be adjacent to the second channel region of the second vertical portion V2 and may control the second channel region.

According to some implementations, lower portions of the first and second word lines WL1 and WL2 may protrude toward each other. For example, widths of the lower portions of the first and second word lines WL1 and WL2 in the first direction D1 may be greater than widths of the upper portions of the first and second word lines WL1 and WL2. However, in some implementations, the widths of the upper and lower portions of the first and second word lines WL1 and WL2 may be substantially the same.

The word line WL may include at least one of, for example, doped polysilicon, metal (e.g., Al, Cu, Ti, Ta, Ru, W, Mo, Pt, Ni, Co), conductive metal nitride (e.g., TiN, TaN, WN, NbN, TiAlN, TiSiN, TaSiN, RuTiN), conductive metal silicides or conductive metal oxides (e.g. PtO, RuO₂, IrO₂, SrRuO₃ (SRO), (Ba,Sr)RuO₃ (BSRO), CaRuO₃ (CRO), LSCo), but is not limited thereto. The word line WL may include a single layer or multiple layers of the above-described materials. In some embodiments, the word line WL may include a two-dimensional semiconductor material, for example, graphene, carbon nanotubes, or a combination thereof.

The gate insulating patterns Gox may be interposed between the semiconductor pattern SP and the word line WL. For example, the gate insulating patterns Gox may be interposed between the inner surfaces of the first vertical portions V1 of the semiconductor patterns SP and the first word line WL1, and between the inner surfaces of the second vertical portions V2 and the second word line WL2. The gate insulating patterns Gox may extend in the second direction D2 across the bit lines BL. The gate insulating patterns Gox may further extend between the horizontal portions H of the semiconductor patterns SP and the word line WL. The word line WL may be separated from the semiconductor patterns SP by the gate insulating patterns Gox, and the gate insulating patterns Gox may cover the semiconductor patterns SP with a uniform thickness.

One of the gate insulating patterns Gox may extend between the first vertical portions V1 of the semiconductor patterns SP to be in contact with side surfaces of each of the first vertical portions V1 facing in the second direction D2. FIG. 3, an outer surface Goxo of one of the gate insulating patterns Gox may be aligned with outer surfaces V1o of the first vertical portions V1 in the second direction D2. Another one of the gate insulating patterns Gox may extend between the second vertical portions V2 of the semiconductor patterns SP to be in contact with side surfaces of the second vertical portions V2 facing in the second direction D2. An outer surface Goxo of another one of the gate insulating patterns Gox may be aligned with an outer surfaces V2o of the second vertical portions V2 in the second direction D2.

In some implementations, as shown in FIG. 7A, the gate insulating patterns Gox may be interposed between the first vertical portion V1 and the first word line WL1, and between the second vertical portion V2 and the second word line WL2, respectively, and may be separated without being connected to each other on the horizontal portion H. Accordingly, the gate insulating patterns Gox may be spaced apart from each other on the horizontal portion H.

In some implementations, the gate insulating patterns Gox may be interposed between the first vertical portion V1 and the first word line WL1, and between the second vertical portion V2 and the second word line WL2 and may be extended on the horizontal portion H to be connected to each other. The gate insulating patterns Gox may include at least one of silicon oxide, silicon oxynitride, and a low dielectric material having a lower dielectric constant than silicon oxide.

First capping patterns CC1 may be interposed between one of the gate insulating patterns Gox and the first vertical portions V1 of the semiconductor patterns SP. Second capping patterns CC2 may be interposed between another one of the gate insulating patterns Gox and the second vertical portions V2 of the semiconductor patterns SP. The first capping patterns CC1 may be spaced apart from each other in the second direction D2 with one of the gate insulating patterns Gox interposed therebetween. The second capping patterns CC2 may be spaced apart from each other in the second direction D2 with the another of the gate insulating patterns Gox interposed therebetween. The first vertical portion V1 and the first capping pattern CC1 of each of the semiconductor patterns SP may have side surfaces facing each other in the second direction D2. The side surfaces of the first vertical portion V1 may be aligned with the side surfaces of the first capping pattern CC1 in the first direction D1. The second vertical portion V2 and the second capping pattern CC2 of each of the semiconductor patterns SP may have side surfaces facing each other in the second direction D2. The side surfaces of the second vertical portion V2 may be aligned with the side surfaces of the second capping pattern CC2 in the first direction D1. In a plan view, widths of the first and second vertical portions V1 and V2 of each of the semiconductor patterns SP in the second direction D2 may be substantially equal to widths of the first and second capping patterns CC1 and CC2 in the second direction D2. The side surfaces of the first and second vertical portions V1 and V2 of each of the semiconductor patterns SP facing in the second direction D2 may be not covered by the first and second capping patterns CC1 and CC2.

The first and second capping patterns CC1 and CC2 may further extend between the horizontal portion H of each of the semiconductor patterns SP and the gate insulating patterns Gox. The word line WL may be spaced apart from the semiconductor patterns SP by the gate insulating patterns Gox and the first and second capping patterns CC1 and CC2. The first and second capping patterns CC1 and CC2 may cover the semiconductor patterns SP with a uniform thickness.

In some implementations, as shown in FIG. 7A, the first and second capping patterns CC1 and CC2 may be interposed between the first vertical portion V1 and the first word line WL1 and between the second vertical portion V2 and the second word line WL2, respectively, and may be separated rather than connected to each other on the horizontal portion H. For example, the first capping pattern CC1 and the second capping pattern CC2 may be spaced apart from each other on the horizontal portion H.

In some implementations, the first and second capping patterns CC1 and CC2 may be interposed between the first vertical portion V1 and the first word line WL1, and between the second vertical portion V2 and the second word line WL2 and may be connected to each other on the horizontal portion H.

One of the gate insulating patterns Gox may have a first thickness T1 in the first direction D1 between the first vertical portions V1. The one of the gate insulating patterns Gox may have a second thickness T2 in the first direction D1 on each of the first vertical portions V1. Each of the first capping patterns CC1 may have a third thickness T3 in the first direction D1 between each of the first vertical portions V1 and one of the gate insulating patterns Gox. A sum of the second thickness T2 and the third thickness T3 may be greater than the first thickness T1. The second thickness T2 may be 4.2 nm to 4.7 nm, and the third thickness T3 may be 1.3 nm to 1.8 nm. Preferably, the second thickness T2 may be 4.5 nm, and the third thickness T3 may be 1.5 nm.

The first and second capping patterns CC1 and CC2 may include at least one of silicon oxide, silicon oxynitride, and a high dielectric material having a higher dielectric constant than silicon oxide. In some implementations, the high dielectric material may include metal oxide or metal oxynitride. For example, the high dielectric material may include at least one of HfO2, HfSiO, HfSiON, HfTaO, HfTiO, HfZrO, ZrO₂, and Al₂O₃, but is not limited thereto.

The first insulating pattern 120 may be interposed between adjacent semiconductor patterns SP in the first direction D1. A plurality of first insulating patterns 120 may be provided. The first insulating patterns 120 may extend in the second direction D2 across the bit line BL and may be spaced apart from each other in the first direction D1. The first insulating pattern 120 may cover at least a portion of outer surfaces of the first and second vertical portions V1 and V2. For example, the first insulating pattern 120 may include at least one of silicon oxide, silicon nitride, silicon oxynitride, and a low dielectric material. In some implementations, the first insulating pattern 120 may be formed of a single layer or multiple layers.

In some implementations, as shown in FIG. 7A, the first insulating pattern 120 may be in contact with the uppermost surface BLa of the bit line BL. The first insulating pattern 120 may cover the outer surfaces of the first and second vertical portions V1 and V2 of the semiconductor pattern SP. A lower surface Hb of the horizontal portion H may be positioned at substantially the same height as a lowermost surface of the first insulating pattern 120.

The second insulating pattern 130 may be disposed between the first word line WL2 and the second word line WL2 of the word line WL. A plurality of second insulating patterns 130 may be provided. The second insulating patterns 130 may extend in the second direction D2 across the bit line BL and may be spaced apart from each other in the first direction D1. The first and second insulating patterns 120 and 130 may be alternately arranged in the first direction D1. The second insulating pattern 130 may include, for example, at least one of silicon oxide, silicon nitride, silicon oxynitride, and a low dielectric material.

A protection pattern 110 may be interposed between the word line WL and the second insulating pattern 130. The protection pattern 110 may cover an inner surface of the word line WL and may extend onto the horizontal portion H of the semiconductor pattern SP. For example, the protection pattern 110 may include at least one of silicon oxide, silicon nitride, and silicon oxynitride.

A capping pattern 220 may be provided on an upper surface of the word line WL. The capping pattern 220 may cover upper surfaces of the protection pattern 110 and the second insulating pattern 130. The capping pattern 220 may extend in the second direction D2. For example, the capping pattern 220 may include at least one of silicon oxide, silicon nitride, and silicon oxynitride.

Landing pads LP may be disposed on the first and second vertical portions V1 and V2 of each of the semiconductor patterns SP. The landing pads LP may be in direct contact with and be electrically connected to the first vertical portion V1 and the second vertical portion V2. In a plan view, the landing pads LP may be spaced apart from each other in the first and second directions D1 and D2 and may be arranged in various shapes, such as a matrix shape, a zigzag shape, or a honeycomb shape. In a plan view, each of the landing pads LP may have various shapes, such as circular, oval, rectangular, square, diamond, or hexagonal shapes.

The landing pads LP may be formed of, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but is not limited thereto.

A third interlayer insulating layer 240 may fill a space between the landing pads LP on the first and second insulating patterns 120 and 130. For example, the third interlayer insulating layer 240 may include at least one of silicon oxide, silicon nitride, and silicon oxynitride, and may include a single layer or multiple layers.

Data storage patterns DSP may be respectively disposed on the landing pads LP. The data storage patterns DSP may be electrically connected to the first vertical portion V1 and the second vertical portion V1 and V2 of each of the semiconductor patterns SP through the landing pads LP.

According to some implementations, the data storage patterns DSP may be a capacitor and may include lower and upper electrodes with a capacitor dielectric layer interposed therebetween. For example, the lower electrode may be in contact with the landing pad LP, and the lower electrode may have various shapes, such as circular, oval, rectangular, square, diamond, or hexagon, in a plan view.

In some implementations, the data storage patterns DSP may be variable resistance patterns that may be switched between two resistance states by electrical pulses applied to a memory element. For example, the data storage patterns DSP may be formed of phase-change materials, perovskite compounds, transition metal oxides, magnetic materials, magnetic materials, ferromagnetic materials, or antiferromagnetic materials, whose crystal state changes depending on the amount of current.

FIG. 7B is a cross-sectional view corresponding to line D-D′ in FIG. 3, according to some implementations. To simplify the explanation, descriptions of content that overlaps with the above-described content are omitted.

In FIG. 7B, each of the semiconductor patterns SP may include a first vertical portion V1 and a second vertical portion V2 facing each other, and the first and second vertical portions V1 and V2 may be spaced apart from each other. A word line WL may be disposed on each of the first and second vertical portions V1 and V2. The word line WL may include a first word line WL1 on an inner surface of the first vertical portion V1, and a second word line WL2 on an inner surface of the second vertical portion V2.

Gate insulating patterns Gox may be interposed between the first vertical portion V1 and the first word line WL1 and between the second vertical portion V2 and the second word line WL2, respectively. The gate insulation patterns Gox may further extend between the bit line BL and the word line WL. The second insulating pattern 130 may fill a space between the first word line WL1 and the second word line WL2. The first capping patterns CC1 may be interposed between one of the gate insulating patterns Gox and the first vertical portions V1 of the semiconductor patterns SP. The second capping patterns CC2 may be interposed between another one of the gate insulating patterns Gox and the second vertical portions V2 of the semiconductor patterns SP. The first and second capping patterns CC1 and CC2 may further extend between the bit line BL and the gate insulating patterns Gox. Lower surfaces Vb of the first and second vertical portions V1 and V2 may be positioned at substantially the same height as lower surfaces CCb of the first and second capping patterns CC1 and CC2.

An upper surface of the bit line BL may extend in a straight line in the first direction D1. A height of the upper surface of the bit line BL may remain substantially the same in the first direction D1. Accordingly, the upper surface of the bit line BL may be the uppermost surface BLa of the bit line BL.

The first and second vertical portions V1 and V2 of each of the semiconductor patterns SP may be provided on the upper surface of the bit line BL. The lower surfaces Vb of the first and second vertical portions V1 and V2 and the lower surfaces CCb of the first and second capping patterns CC1 and CC2 may be in contact with the uppermost surface BLa of the bit line BL and may be positioned at substantially the same height as the uppermost surface BLa of the bit line BL.

In some implementations, as shown in FIG. 7B, the first insulating pattern 120 may be in contact with the uppermost surface BLa of the bit line BL. The first insulating pattern 120 may cover outer surfaces of the first and second vertical portions V1 and V2 of each of the semiconductor patterns SP. The lower surfaces Vb of the first and second vertical portions V1 and V2 and the lower surfaces CCb of the first and second capping patterns CC1 and CC2 may be positioned at substantially the same height as a lowermost surfaces of the first insulating pattern 120.

FIG. 7C is a cross-sectional view corresponding to line D-D′ in FIG. 3, according to some implementations. To simplify the explanation, descriptions of content that overlaps with the above-described content are omitted.

In FIG. 7C, an upper surface of the bit line BL may have a concave-convex structure. The upper surface of the bit line BL below the semiconductor pattern SP may be positioned at a lower height than the uppermost surface BLa of the bit line BL. The uppermost surface BLa of the bit line BL may be an upper surface positioned at the highest height among the upper surfaces of the bit line BL and may be provided in a region that does not vertically overlap the semiconductor pattern SP.

In some implementations, a lower surface Hb of the horizontal portion H of each of the semiconductor patterns SP may be positioned at a lower height than the uppermost surface BLa of the bit line BL. For example, the lower surface Hb of the horizontal portion H may be a portion positioned at the lowest height among the lower surfaces of the horizontal portion H, but is not limited thereto. At least a portion of the horizontal portion H may be buried in an upper portion of the bit line BL. For example, as shown in FIG. 7C, an upper surface of the horizontal portion H may be located at a lower height than the uppermost surface BLa of the bit line BL, but is not limited thereto. In some implementations, the upper surface of the horizontal portion H may be positioned at a height higher than or at the same level as the uppermost surface BLa of the bit line BL.

Lower portions of the first and second vertical portions V1 and V2 may be buried in the upper portion of the bit line BL. Lower surfaces Vb of the first and second vertical portions V1 and V2 may be substantially coplanar with the lower surface Hb of the horizontal portion H, and may be positioned at a height lower than the uppermost surface BLa of the bit line BL. For example, each of the lower surfaces Vb of the first and second vertical portions V1 and V2 may include a portion positioned at the lowest height among the lower surfaces Vb of the first and second vertical portions V1 and V2, but is not limited thereto. Outer surfaces of lower portions of the first and second vertical portions V1 and V2 may be surrounded by the bit line BL.

Due to the bit line BL having the concave-convex structure, a portion of the word line WL may be buried in the upper portion of the bit line BL. Accordingly, the buried portion of the word line WL may horizontally overlap the bit line BL. The word line WL may effectively control each of the first and second channel regions to lower surfaces thereof (e.g., to a lower surface of each of the first and second channel regions provided at a height lower than the uppermost surface BLa of the bit line BL), and as a result, electrical characteristics and reliability of the semiconductor device may be improved.

The first insulating pattern 120 may be in contact with the uppermost surface BLa of the bit line BL. The first insulating pattern 120 may cover a portion of the outer surfaces of the first and second vertical portions V1 and V2 that are not buried by the bit line BL. The lower surface Hb of the horizontal portion H of each of the semiconductor patterns SP may be positioned at a lower height than the lowermost surface of the first insulating pattern 120.

The gate insulating patterns Gox may be interposed between the first vertical portion V1 and the first word line WL1 and between the second vertical portion V2 and the second word line WL2, respectively, and may be extended on the horizontal portion H to be connected each other. The first and second capping patterns CC1 and CC2 may be interposed between the one of the gate insulating patterns Gox and the first vertical portion V1 and between the another one of the gate insulating patterns Gox and the second vertical portion V2, respectively. The first and second capping patterns CC1 and CC2 may further extend between the horizontal portions H of the semiconductor patterns SP and the gate insulating patterns Gox. Lower surfaces CCb of the first and second capping patterns CC1 and CC2 may be positioned at a lower height than the uppermost surface BLa of the bit line BL.

FIG. 7D is a cross-sectional view corresponding to line D-D′ in FIG. 3 according to some implementations. To simplify the explanation, descriptions of content that overlaps with the above-described content are omitted.

In FIG. 7D, each of the semiconductor patterns SP may include a first vertical portion V1 and a second vertical portion V2 facing each other, and the first and second vertical portions V1 and V2 may be spaced apart from each other. A word line WL may be disposed on each of the first and second vertical portions V1 and V2. The word line WL may include a first word line WL1 on an inner surface of the first vertical portion V1 and a second word line WL2 on an inner surface of the second vertical portion V2. Gate insulating patterns Gox may be interposed between the first vertical portion V1 and the first word line WL1 and between the second vertical portion V2 and the second word line WL2, respectively. First and second capping patterns CC1 and CC2 may be interposed between one of the gate insulating patterns Gox and the first vertical portion V1 and between another one of the gate insulating patterns Gox and the second vertical portion V2. The first and second capping patterns CC1 and CC2 may further extend between the bit line BL and the gate insulating patterns Gox. A second insulating pattern 130 may fill a space between the first word line WL1 and the second word line WL2. Lower surfaces Vb of the first and second vertical portions V1 and V2 may be positioned at substantially the same height as lower surfaces CCb of the first and second capping patterns CC1 and CC2.

An upper surface of the bit line BL may have a concave-convex structure. Below a region from an outer surface of the first vertical portion V1 to an outer surface of the second vertical portion V2, an upper surface of the bit line BL may be recessed. Below a region between the semiconductor patterns SP adjacent to each other in the first direction D1, the bit line BL may have an uppermost surface BLa.

Lower portions of the first and second vertical portions V1 and V2, lower portions of the first and second capping patterns CC1 and CC2, and lower portions of the gate insulating pattern Gox may be buried in upper portions of the bit line BL. The lower surfaces Vb of the first and second vertical portions V1 and V2, the lower surfaces CCb of the first and second capping patterns CC1 and CC2, lower surfaces Goxb of the gate insulating patterns Gox may be positioned at a lower height than the uppermost surface BLa of the bit line BL. Lower portions of the first and second vertical portions V1 and V2 may be in contact with the bit line BL. For example, a portion of the word line WL may be buried in the upper portion of the bit line BL. The buried portion of the word line WL may horizontally overlap the bit line BL. The lower surfaces of the first and second word lines WL1 and WL2 may be positioned at a lower height than the uppermost surface BLa of the bit line BL.

The first insulating pattern 120 may be in contact with the uppermost surface BLa of the bit line BL. The first insulating pattern 120 may cover the outer surfaces of the first and second vertical portions V1 and V2 of the semiconductor pattern SP. The lower surfaces Vb of the first and second vertical portions V1 and V2, the bottom surfaces CCb of the first and second capping patterns CC1 and CC2, and the lower surfaces Goxb of the gate insulating pattern Gox may be positioned at a lower height than a lowest surface of the first insulating pattern 120.

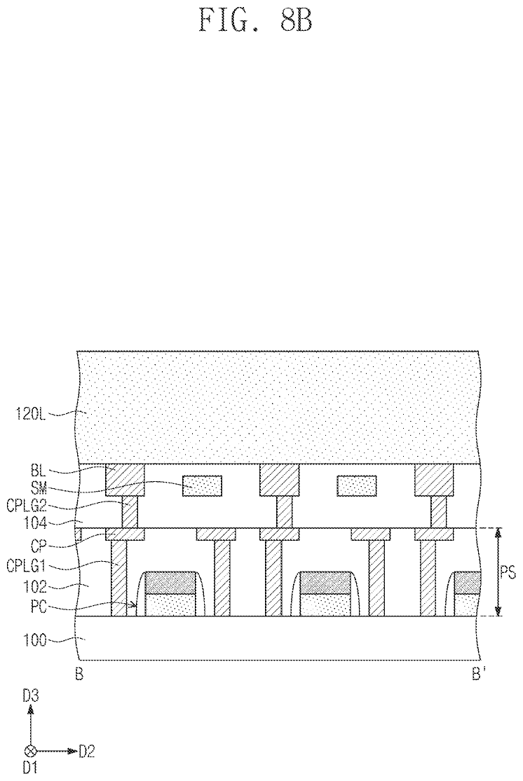

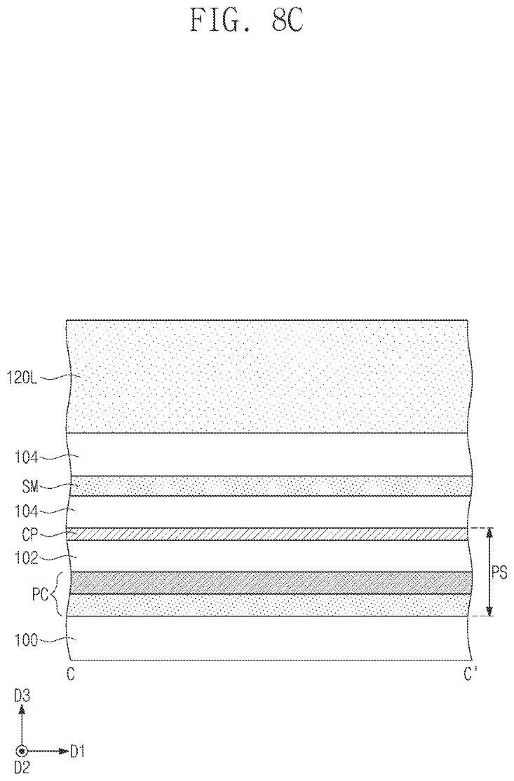

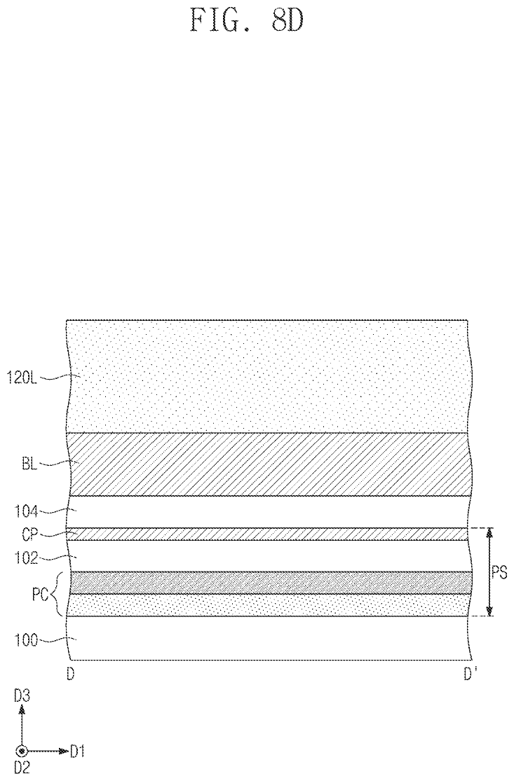

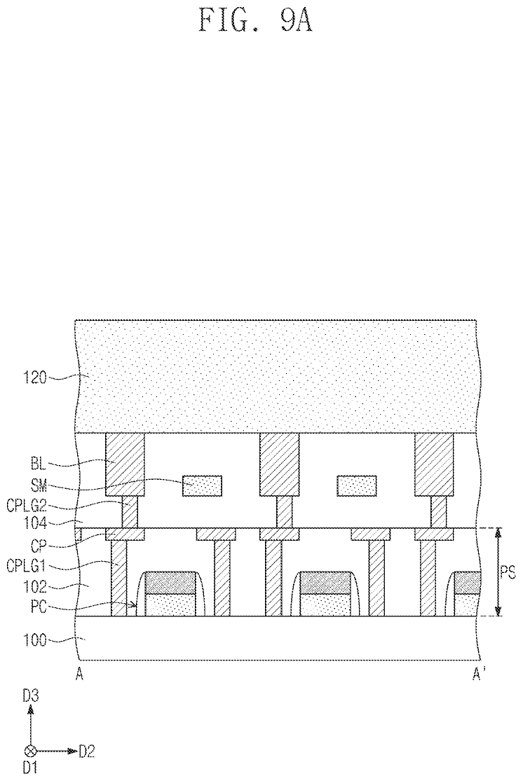

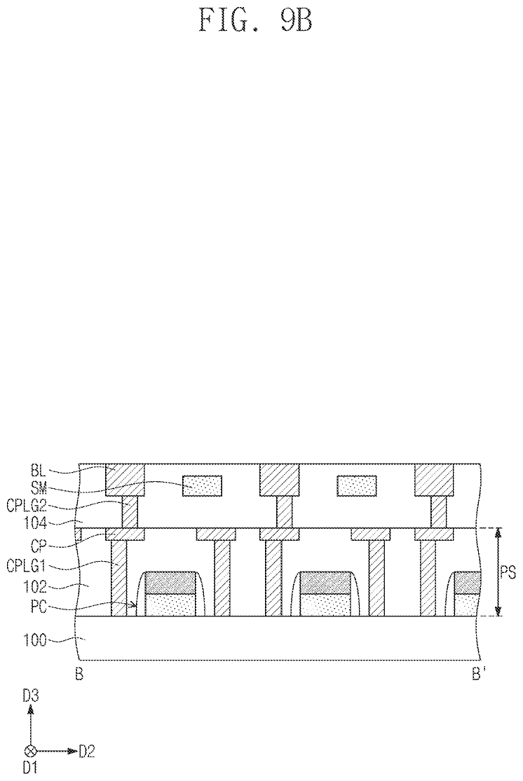

FIGS. 8A to 13D are cross-sectional views illustrating an example of a method of manufacturing the semiconductor device of FIGS. 7A and 7B according to some implementations. Hereinafter, the exemplary method of manufacturing the semiconductor device of FIGS. 7A and 7B will be described with reference to FIGS. 3 and 8A to 13D. To simplify the explanation, descriptions of content that overlaps with the above-described content are omitted.

In FIGS. 3 and 8A to 8D, a peripheral circuit structure PS may be formed on a substrate 100. Forming the peripheral circuit structure PS may include forming a peripheral gate structure PC, peripheral contact pads CP, peripheral contact plugs CPLG1, and a first interlayer insulating layer 102 covering them. A second interlayer insulating layer 104 may be formed on the peripheral circuit structure PS. A bit line BL may be formed in the second interlayer insulating layer 104. A plurality of bit lines BL may be formed. The bit lines BL may extend in a first direction D1 and be spaced apart from each other in a second direction D2. The bit line BL may be formed to be electrically connected to lower wirings and wirings in the peripheral circuit structure PS. Forming the bit line BL may include depositing a bit line layer (not shown) and patterning the bit line layer to form the bit line BL. A shielding structure SM may be formed in the second interlayer insulating layer 104. A plurality of shielding structures SM may be formed. Forming the shielding structures SM may include depositing a shielding layer (not shown) and patterning the shielding layer to form the shielding structures SM.

In FIG. 8B, a first insulating layer 120L may be formed on the second interlayer insulating layer 104 and the bit line BL. The first insulating layer 120L may entirely cover the second interlayer insulating layer 104 and the bit line BL. The first insulating layer 120L may include, for example, at least one of silicon oxide, silicon nitride, silicon oxynitride, and a low dielectric material.

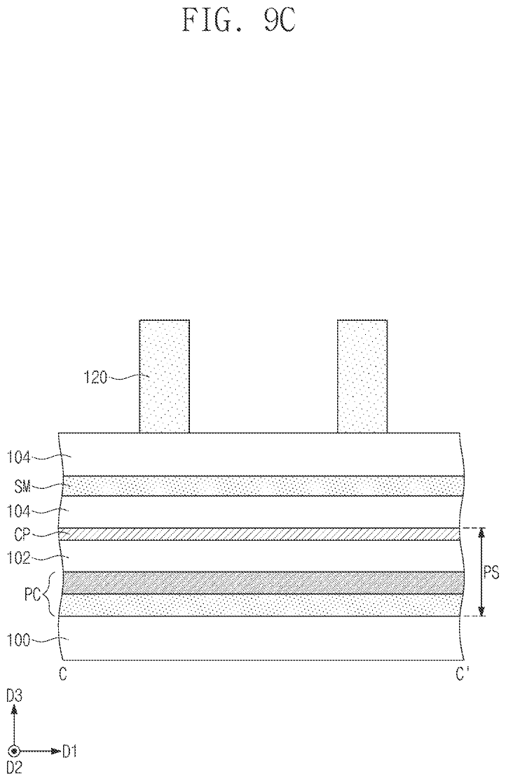

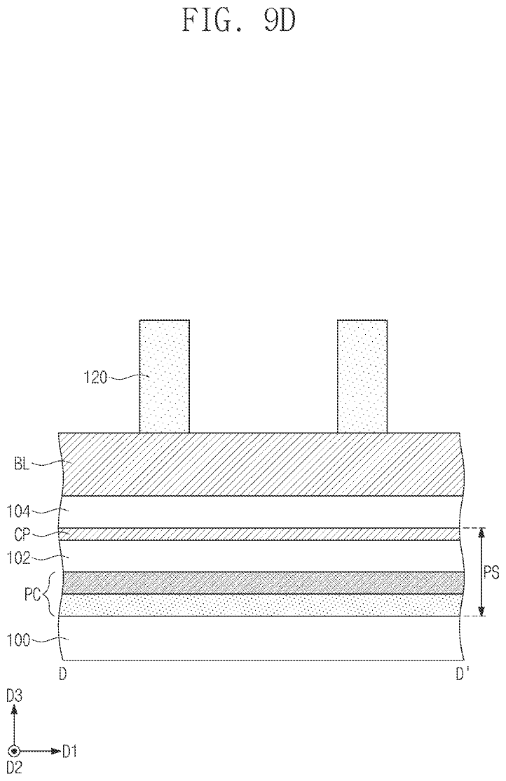

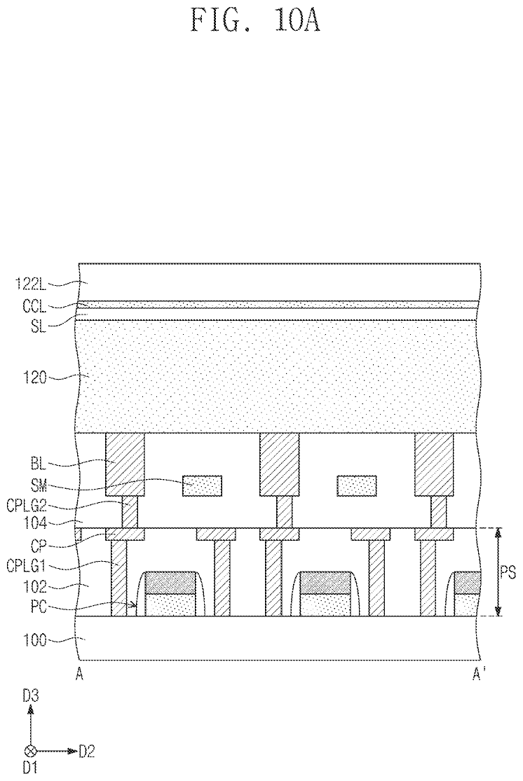

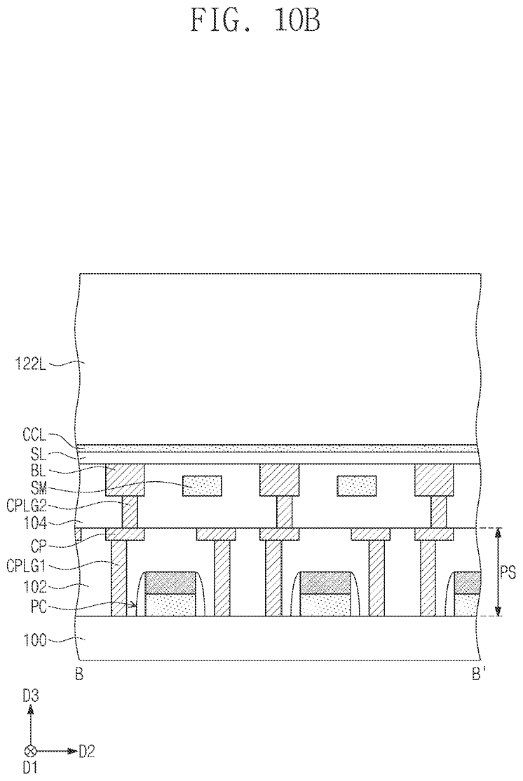

In FIGS. 3 and 9A to 9D, a first insulating pattern 120 may be formed. Forming the first insulating pattern 120 may include forming a mask pattern on the first insulating layer 120L and etching the first insulating layer 120L using the mask pattern as an etch mask, and removing the mask pattern. In the etching process, the bit line BL and the second interlayer insulating layer 104 may not be etched. In FIGS. 9C and 9D, a plurality of first insulating patterns 120 may be formed. The first insulating patterns 120 may extend in the second direction D2 and be spaced apart from each other in the first direction D1.

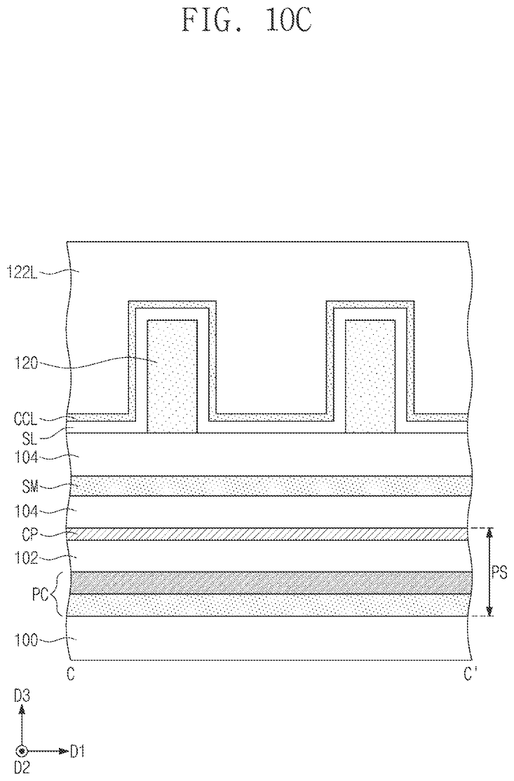

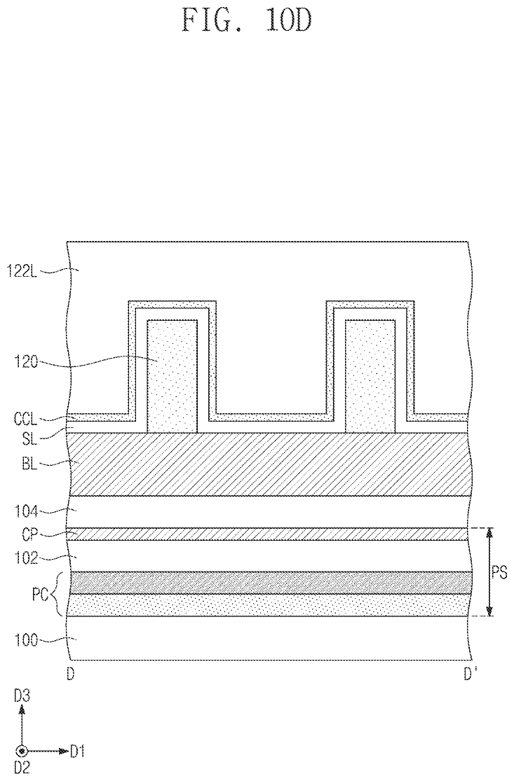

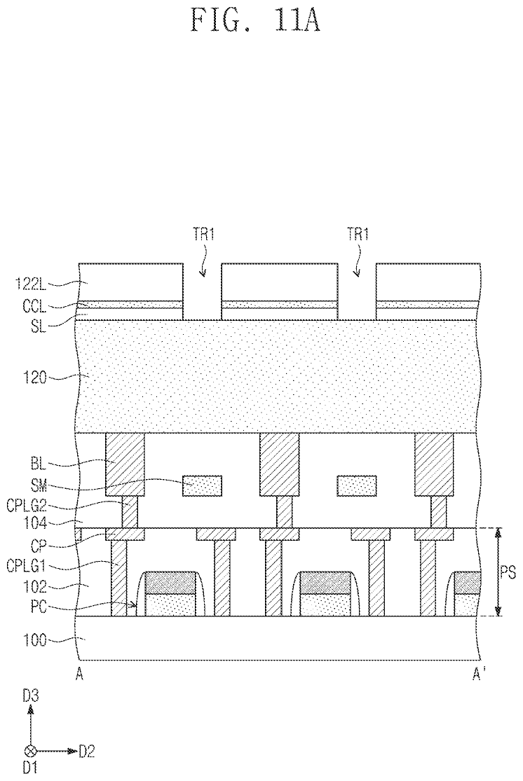

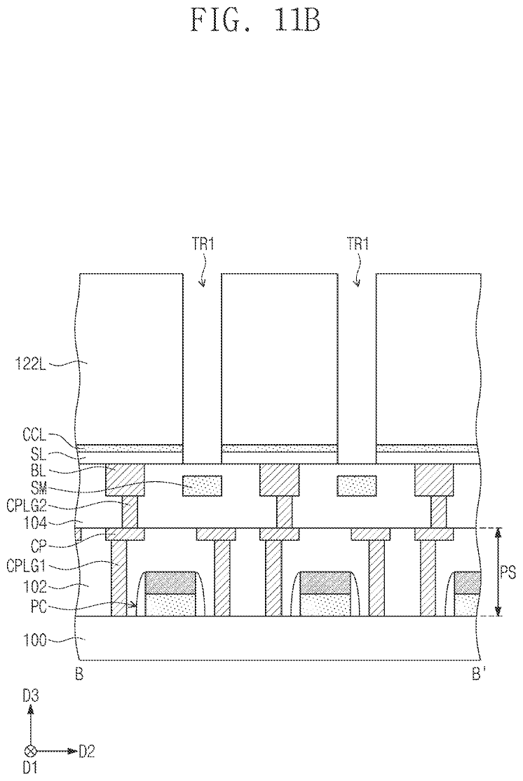

In FIGS. 3 and 10A to 10D, a semiconductor layer SL, a capping layer CCL, and a first mold layer 122L may be formed to cover the first insulating pattern 120. Forming the semiconductor layer SL, capping layer CCL, and first mold layer 122L may be formed using a layer-forming technology, such as chemical vapor deposition CVD, physical vapor deposition PVD, or atomic layer deposition ALD. The semiconductor layer SL and the capping layer CCL may conformally cover the first insulating pattern 120 and extend to an upper surface of the second interlayer insulating layer 104. The first mold layer 122L may entirely cover the capping layer CCL.

In some implementations, the first mold layer 122L may include a material containing carbon. For example, the first mold layer 122L may include a spin-on hardmask (SOH) and an amorphous carbon layer (ACL).

The capping layer CCL may include at least one of silicon oxide, silicon oxynitride, and a high dielectric material having a higher dielectric constant than silicon oxide.

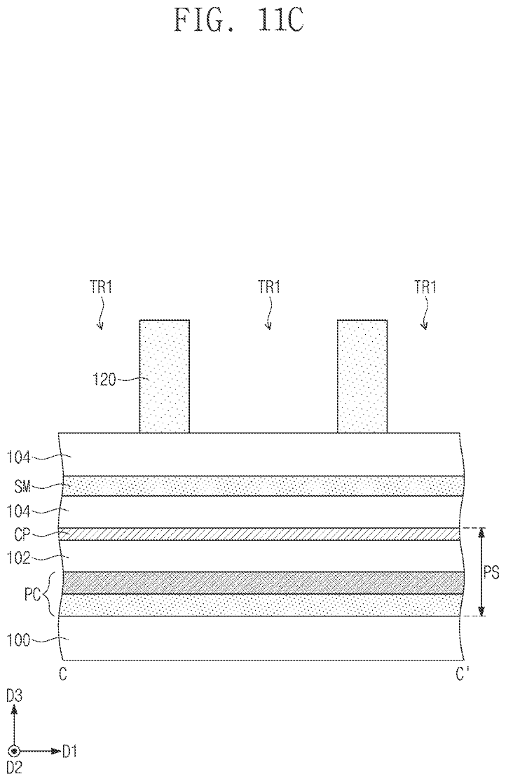

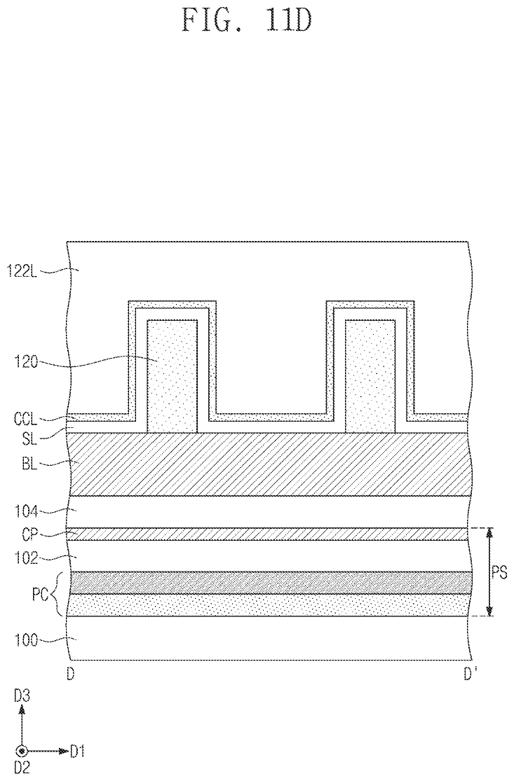

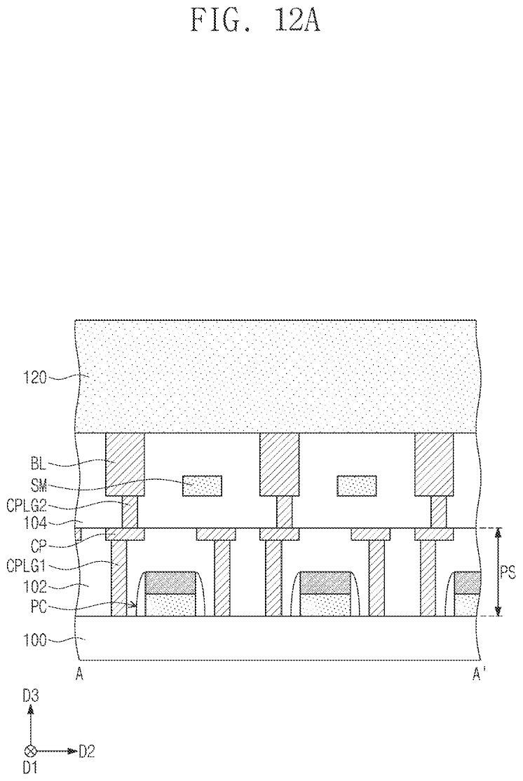

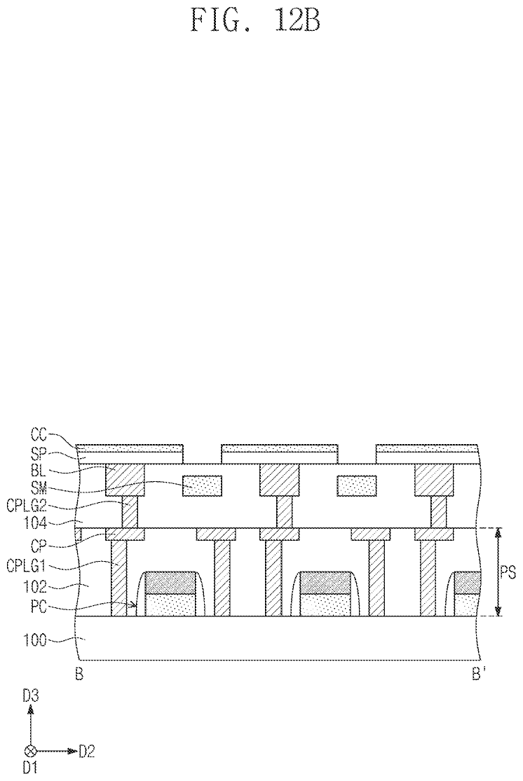

In FIGS. 3 and 11A to 11D, a first trench TR1 may be formed. Forming the first trench TR1 may include forming a mask pattern on the first mold layer 122L, sequentially etching the first mold layer 122L, the capping layer CCL, and the semiconductor layer SL using the mask pattern as an etch mask, and removing the mask pattern. The etching process may include an anisotropic etching process. In the etching process, the second interlayer insulating layer 104 and the first insulating pattern 120 may not be etched. In a plan view, the first trench TR1 may be formed in an region that does not vertically overlap the bit line BL. A plurality of first trenches TR1 may be formed. The first trenches TR1 may extend in the first direction D1 and may be spaced apart from each other in the second direction D2.

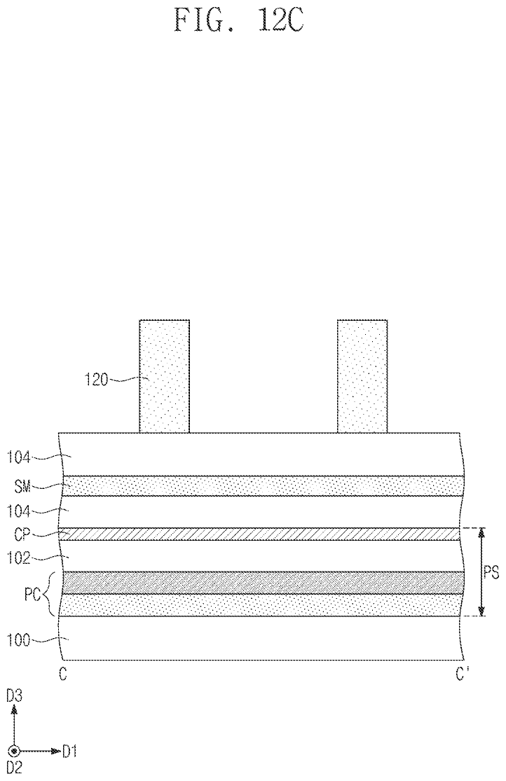

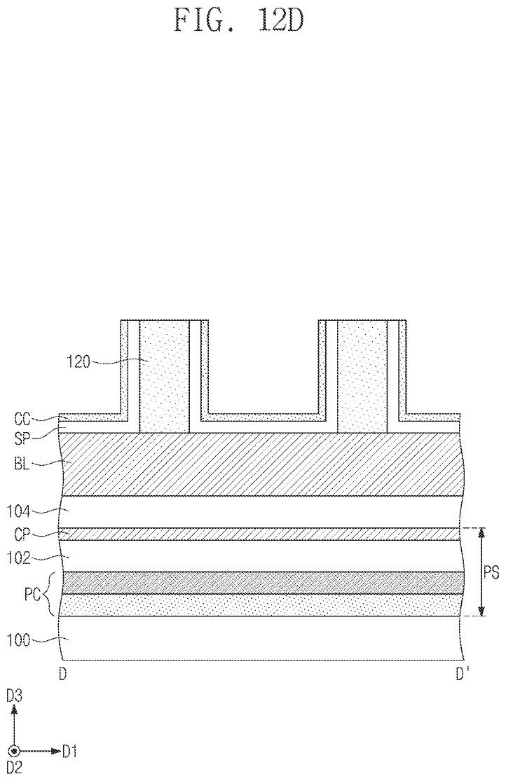

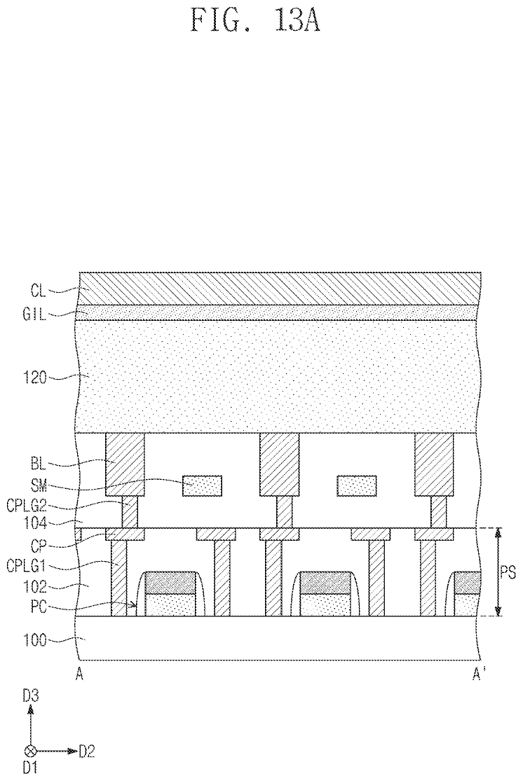

In FIGS. 3 and 12A to 12D, a semiconductor pattern SP and a channel capping pattern CC may be formed. Forming the semiconductor pattern SP and the channel capping pattern CC may include filling the first trenches TR1 with a second mold layer, removing an upper portion of the first mold layer 122L and the second mold layer, removing a portion of the capping layer CCL, removing a portion of the semiconductor layer SL, and removing the remainder of the first mold layer 122L and the second mold layer.

The removing of the upper portions of the first mold layer 122L and the second mold layer, the removing of the portion of the capping layer CCL, and the removing of the portion of the semiconductor layer SL may be performed through a planarization process. Planarization may be performed, for example, through a chemical mechanical polishing CMP process or an etch back process. The planarization process may be performed until upper surfaces of the first insulating patterns 120 are exposed.

A plurality of semiconductor patterns SP may be formed by partially removing the semiconductor layer SL. Each of the semiconductor patterns SP may include a first vertical portion V1, a second vertical portion V2 facing each other, and a horizontal portion H connecting the first and second vertical portions V1 and V2.

In the process of removing the semiconductor layer SL, the horizontal portion H of the semiconductor pattern SP may also be removed. Accordingly, as shown in FIG. 7B, the semiconductor pattern SP may include first and second vertical portions V1 and V2, and the first and second vertical portions V1 and V2 may be spaced apart from each other.

In some implementations, the second mold layer may include a material containing carbon. For example, the second mold layer may include a spin-on hardmask (SOH) and an amorphous carbon layer (ACL).

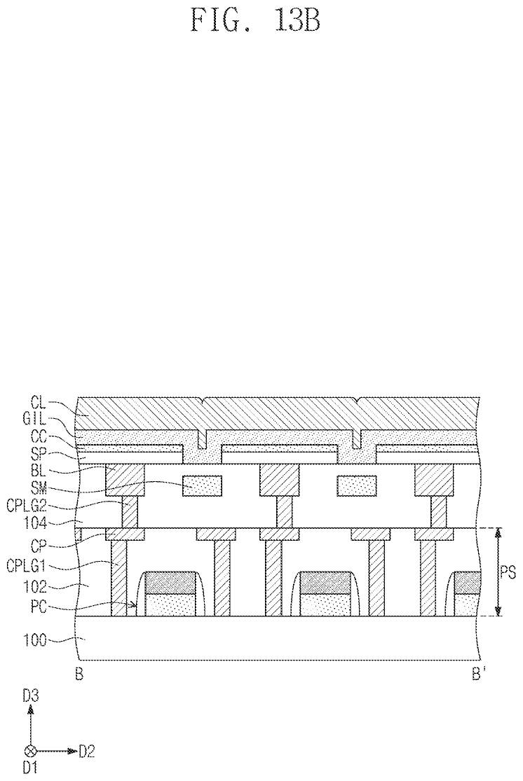

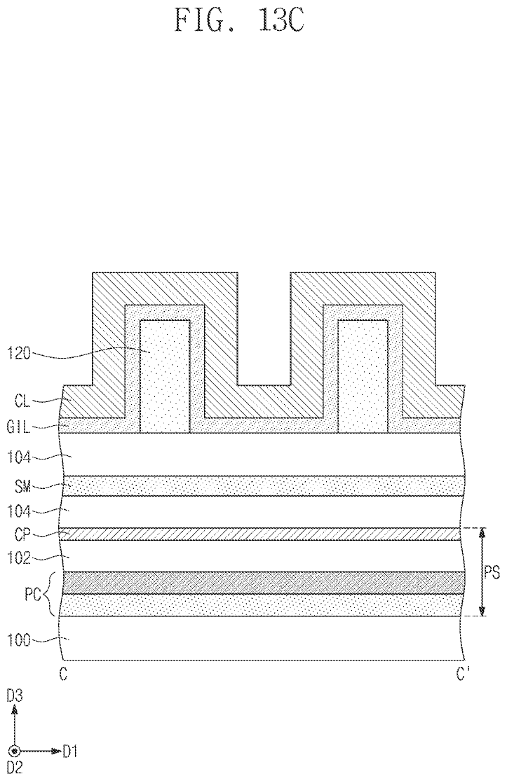

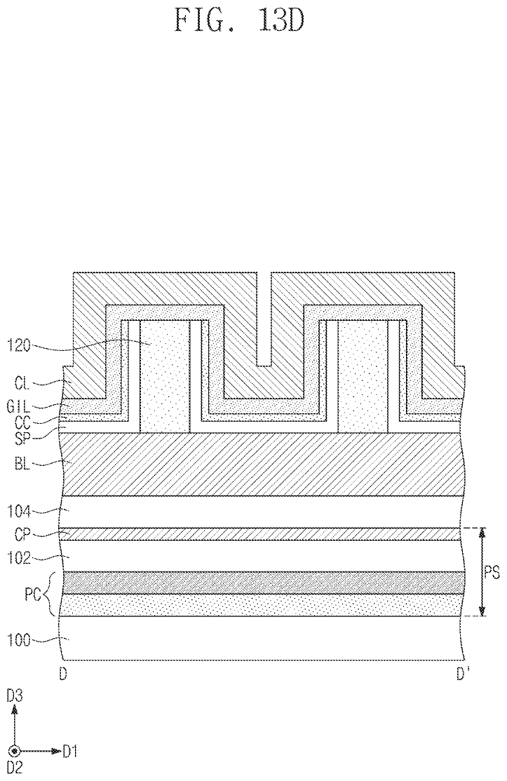

In FIGS. 3 and 13A to 13D, a gate insulating layer GIL and a conductive layer CL may be formed sequentially. Forming the gate insulating layer GIL and conductive layer CL may be formed using a layer-forming technology with excellent step coverage, such as chemical vapor deposition (CVD), physical vapor deposition (PVD), and atomic layer deposition (ALD). The gate insulating layer GIL may conformally cover a side surface and an upper surface of the first insulating pattern 120, an exposed upper surface of the second interlayer insulating layer 104, an upper surface of the semiconductor pattern SP, and the channel capping pattern CC. The conductive layer CL may conformally cover the gate insulating layer GIL.

In FIGS. 3 and 7A, a word line WL and a gate insulating pattern Gox may be formed. The word line WL may be formed to include a first word line WL1 on the first vertical portion V1 and a second word line WL2 on the second vertical portion V2. Forming the word line WL may include, for example, removing the conductive layer CL on the first insulating pattern 120 and the horizontal portion H to separate the conductive layer CL into a plurality of word lines WL.

When forming the word line WL, the gate insulating layer GIL on the first insulating pattern 120 and the horizontal portion H may be removed and separated into a plurality of gate insulating patterns Gox. For example, when forming the word line WL, the gate insulating layer GIL on the first insulating pattern 120 may be removed and separated into a plurality of gate insulating patterns Gox, and the gate insulating layer GIL on the horizontal portion H may remain without being removed and to form a portion of the gate insulating pattern Gox. Accordingly, the gate insulating pattern GIL may have a U-shape connected on the horizontal portion H.

In some implementations, when forming the word line WL and the gate insulating pattern Gox, a portion of the horizontal portion H of the semiconductor pattern SP may be further removed. Accordingly, the horizontal portion H may be divided into first and second sub-horizontal portions connected to the first and second vertical portions V1 and V2, respectively, and the first and second sub-horizontal portions may be spaced apart from each other. The first vertical portion V1 and the first sub-horizontal portion may be connected to each other to have an L-shape, and the second vertical portion V2 and the second sub-horizontal portion may be connected to each other to have an L-shape.

In some implementations, an upper surface of the word line WL may be formed to be positioned at a lower height than an upper surface of the gate insulating pattern Gox and an upper surface of the first insulating pattern 120.

When forming the word line WL, a portion of the channel capping pattern CC may be removed to form a first capping pattern CC1 and a second capping pattern CC2. Removing a portion of the channel capping pattern CC may include removing the channel capping pattern CC between the first insulating patterns 120.

A protection pattern 110 may be formed along inner surfaces of the word lines WL. Forming the protection pattern 110 may include forming a protective layer that conformally covers the inner surfaces of the word lines WL, and removing a portion of the protective layer.

The second insulating pattern 130 may be formed between the first word line WL1 and the second word line WL2. Forming the second insulating pattern 130 may include forming a second insulating layer covering the semiconductor pattern SP, gate insulating pattern Gox, and word line WL, and removing an upper portion of the second insulating layer to separate into a plurality of second insulating patterns 130. The upper surface of the second insulating pattern 130 may be positioned at a lower height than an upper surface of the gate insulating pattern Gox and an upper surface of the first insulating pattern 120, and may be formed at a height adjacent to an upper surface of the word line WL.

A capping pattern 220 may be formed on the upper surface of the word line WL, the upper surface of the protection pattern 110, and the upper surface of the second insulating pattern 130. When forming the capping pattern 220, the upper surface of the first insulating pattern 120 and the upper surfaces of the first and second vertical portions V1 and V2 may be exposed to the outside.

Landing pads LP may be formed on the first and second vertical portions V1 and V2 of the semiconductor pattern SP, respectively. Forming the landing pads LP may include removing upper portions of the first and second vertical portions V1 and V2 to form a recessed region, forming a landing pad layer (not shown) to fill the recessed region and cover the capping pattern 220, and separating a portion of the landing pad layer into a plurality of landing pads.

A third interlayer insulating layer 240 may be formed to fill a space between the landing pads LP on the first and second insulating patterns 120 and 130. Data storage patterns DSP may be formed on the landing pads LP, respectively. The data storage patterns DSP may be electrically connected to the first and second vertical portions V1 and V2 of the semiconductor pattern SP through the landing pads LP, respectively.

When forming a channel in an oxide semiconductor with a vertical channel structure, a channel material is deposited and then the channel is separated through an etching process using an etch mask. However, there is a problem that interfacial by-products may occur due to depositing an etch mask on the channel material, and as a result, electrical characteristics and reliability of the device are deteriorated.

According to some implementations, as described above with reference to FIGS. 8A to 13D, the capping layer CCL may be deposited after forming the semiconductor layer SL, which is the channel material. When the semiconductor pattern SP is formed by separating the channel in a subsequent process, the channel capping pattern CC may be on the semiconductor pattern SP. A portion of the semiconductor pattern SP except for the side surfaces facing in the second direction D2 may be covered by the channel capping pattern CC. Accordingly, the portion covered by the channel capping pattern CC may avoid direct contact of the semiconductor layer SL with the etch mask. Accordingly, the interfacial by-products may be prevented from occurring in the channel material, and to provide a semiconductor device with the improved electrical characteristics and reliability.

Additionally, according to some implementations, the first and second capping patterns CC1 and CC2 may include a high dielectric material. The first and second capping patterns CC1 and CC2 that are in direct contact with the semiconductor pattern SP may include a high dielectric material, thereby increasing a capacitance of the device. In addition, the gate insulation patterns Gox may include a low dielectric material to prevent crosstalk between adjacent cells. Accordingly, a semiconductor device with improved electrical characteristics and reliability may be provided.

Additionally, according to some implementations, the third thickness T3 of the first capping patterns CC1 may be 1.3 nm to 1.8 nm. The second thickness T2 of the gate insulating patterns Gox may be 4.2 nm to 4.7 nm. Preferably, the second thickness T2 may be 4.5 nm, and the third thickness T3 may be 1.5 nm. In the corresponding thickness range, the electrical characteristics and reliability of the semiconductor device may not deteriorate compared to the conventional semiconductor device.

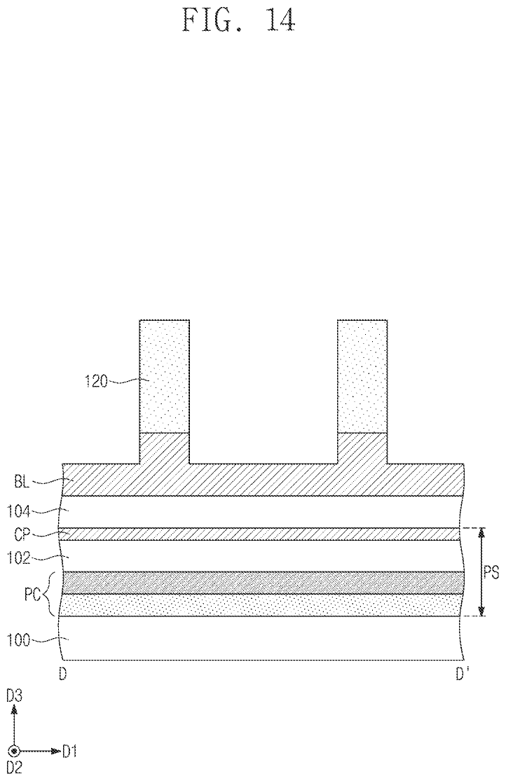

FIG. 14 is a cross-sectional view illustrating an example of a process of manufacturing the semiconductor device of FIGS. 7C and 7D according to some implementations. To simplify the explanation, descriptions of content that overlaps with the above-described content are omitted.

In FIG. 14, a first insulating pattern 120 may be formed. Forming the first insulating pattern 120 may include forming a mask pattern on the first insulating layer 120L, etching the first insulating layer 120L using the mask pattern as an etch mask, and removing the mask pattern. In the etching process, a portion of the upper portion of the bit line BL may be recessed. Accordingly, an upper surface of the bit line BL may have a concave-convex structure.

In a subsequent process, through substantially the same process as described above with reference to FIGS. 10A to 13D, a semiconductor pattern SP may include a first vertical portion V1, a second vertical portion V2, and a horizontal portion H connecting the first and second vertical portions V1 and V2. When forming the semiconductor pattern SP, lower portions of the first and second vertical portions V1 and V2 and at least a portion of the horizontal portion H may be buried in an upper portion of the bit line BL. Accordingly, the semiconductor device shown in FIG. 7C may be manufactured through the above-described subsequent process.

In some implementations, when forming the semiconductor pattern SP, the horizontal portion H may be removed. Accordingly, as shown in FIG. 7D, the semiconductor pattern SP may include first and second vertical portions V1 and V2, and the first and second vertical portions V1 and V2 may be spaced apart from each other. In a subsequent process, the semiconductor device shown in FIG. 7D may be manufactured through substantially the same process as described above with reference to FIGS. 10A to 13D.

According to some implementations, no interfacial by-products may be generated in the channel material, thereby improving the electrical characteristics and reliability of the semiconductor device.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a plurality of bit lines, each bit line of the plurality of bit lines extending in a first direction;
a plurality of semiconductor patterns disposed on the plurality of bit lines, each semiconductor pattern of the plurality of semiconductor patterns including a first vertical portion and a second vertical portion facing each other in the first direction, and a horizontal portion connecting the first vertical portion and the second vertical portion;
a first word line and a second word line, both extending in a second direction across the plurality of bit lines the first word line being disposed adjacent to the first vertical portions of the plurality of semiconductor patterns, the second word line being disposed adjacent to the second vertical portions of the plurality of semiconductor patterns, and both the first word line and the second word line being disposed on the horizontal portion of the plurality of semiconductor patterns;
a plurality of gate insulating patterns, each gate insulating pattern of the plurality of gate insulating patterns being interposed between the first vertical portions and the first word line, and between the second vertical portions and the second word line, and extending in the second direction across the plurality of bit lines; and
a plurality of first capping patterns, each first capping pattern of the plurality of first capping patterns being interposed between one of the plurality of gate insulating patterns and the first vertical portions; and
a plurality of second capping patterns, each second capping pattern of the plurality of second capping patterns being interposed between another one of the plurality of gate insulating patterns and the second vertical portions,
wherein each first capping pattern of the plurality of first capping patterns is spaced apart from each other in the second direction with the one of the plurality of gate insulating patterns interposed therebetween, and
wherein each second capping pattern of the plurality of second capping patterns is spaced apart from each other in the second direction with the another one of the plurality of gate insulating patterns interposed therebetween.

2. The semiconductor device of claim 1,
wherein each first vertical portion of the first vertical portions of the plurality of semiconductor patterns has side surfaces facing each other in the second direction,
wherein each first capping pattern of the plurality of first capping patterns has side surfaces facing each other in the second direction, respectively, and
wherein the side surfaces of each of the first vertical portions are aligned with the side surfaces of each of the plurality of first capping patterns along the first direction.

3. The semiconductor device of claim 1, wherein the one of the plurality of gate insulating patterns extends between the first vertical portions of the plurality of semiconductor patterns and is in contact with side surfaces of each of the first vertical portions facing in the second direction.

4. The semiconductor device of claim 3, wherein an outer surface of the one of the plurality of gate insulating patterns between the first vertical portions of the plurality of semiconductor patterns is aligned with outer surfaces of the first vertical portions of the plurality of semiconductor patterns along the second direction.

5. The semiconductor device of claim 1, wherein the one of the plurality of gate insulating patterns has a first thickness in the first direction between the first vertical portions of the plurality of semiconductor patterns and a second thickness in the first direction on each of the first vertical portions,
wherein each of the plurality of first capping patterns has a third thickness in the first direction between each of the first vertical portions of the plurality of semiconductor patterns and the one of the plurality of gate insulating patterns, and
wherein a sum of the second thickness and the third thickness is greater than the first thickness.

6. The semiconductor device of claim 5,
wherein the third thickness is 1.3 nm to 1.8 nm, and
wherein the second thickness is 4.2 nm to 4.7 nm.

7. The semiconductor device of claim 1, wherein the plurality of first capping patterns and the plurality of the second capping patterns include at least one of HfO₂, HfSiO, HfSiON, HfTaO, HfTiO, HfZrO, ZrO₂, and Al₂O₃, and
wherein the plurality of gate insulating patterns include at least one of silicon oxide, silicon nitride, silicon oxynitride, and a low dielectric material.

8. The semiconductor device of claim 1, wherein at least a portion of the horizontal portion of each of the plurality of semiconductor patterns is buried in an upper portion of a corresponding one of the plurality of bit lines.

9. The semiconductor device of claim 1, wherein a lower surface of the horizontal portion of each of the plurality of semiconductor patterns is positioned at a same height as an uppermost surface of a corresponding one of the plurality of bit lines.

10. The semiconductor device of claim 1, further comprising:
a plurality of landing pads, each disposed on the first vertical portion and the second vertical portion of the plurality of semiconductor patterns; and
a plurality of data storage patterns disposed on the plurality of landing pads.

11. A semiconductor device comprising:
a plurality of bit lines, each bit line of the plurality of bit lines extending in a first direction;
a plurality of semiconductor patterns disposed on the plurality of bit lines, each semiconductor pattern of the plurality of semiconductor patterns including a first vertical portion and a second vertical portion facing each other in the first direction;
a first word line and a second word line, both extending in a second direction across the plurality of bit lines, the first word line being disposed on inner surfaces of the first vertical portions and the second word line being disposed on inner surfaces of the second vertical portions of the plurality of semiconductor patterns;
a gate insulating pattern interposed between the first vertical portions of the plurality of semiconductor patterns and the first word line, and extending in the second direction across the plurality of bit lines; and
a plurality of first capping patterns interposed between the gate insulating pattern and the first vertical portions of the plurality of semiconductor patterns,
wherein the plurality of first capping patterns are spaced apart from each other in the second direction with the gate insulating pattern therebetween.

12. The semiconductor device of claim 11,
wherein the first vertical portions of each of the plurality of semiconductor patterns have side surfaces facing each other in the second direction,
wherein each of the plurality of first capping patterns have side surfaces facing each other in the second direction, respectively, and
wherein the side surfaces of each of the plurality of first capping patterns are aligned with the side surfaces of each of the first vertical portions along the first direction.

13. The semiconductor device of claim 11, wherein the gate insulating pattern extends between the first vertical portions of the plurality of semiconductor patterns and is in contact with side surfaces of each of the first vertical portions facing in the second direction.

14. The semiconductor device of claim 13, wherein an outer surface of the gate insulating pattern between the first vertical portions is aligned with outer surfaces of the first vertical portions in the second direction.

15. The semiconductor device of claim 11, wherein the gate insulating pattern has a first thickness in the first direction between the first vertical portions of the plurality of semiconductor patterns and a second thickness in the first direction on each of the first vertical portions,
wherein each of the plurality of first capping patterns has a third thickness in the first direction between each of the first vertical portions and the gate insulating pattern,
wherein a sum of the second thickness and the third thickness is greater than the first thickness.

16. The semiconductor device of claim 11, wherein lower surfaces of the first vertical portions of the plurality of semiconductor patterns and the second vertical portions of the plurality of semiconductor patterns are positioned at a same height as an uppermost surface of the plurality of bit lines.

17. The semiconductor device of claim 11, wherein lower surfaces of the first vertical portions of the plurality of semiconductor patterns and the second vertical portions of the plurality of semiconductor patterns are positioned at a lower height than an uppermost surface of the plurality of bit lines.

18. A semiconductor device comprising:
peripheral circuit structures on a substrate;
an interlayer insulating layer on the peripheral circuit structure;
a plurality of bit lines and a plurality of shielding structures extending in a first direction in the interlayer insulating layer, each bit line of the plurality of bit lines and each shielding structure of the plurality of shielding structures being spaced apart from each other in a second direction and arranged in an alternating pattern;
a plurality of semiconductor patterns disposed on the plurality of bit lines, each semiconductor pattern of the plurality of semiconductor patterns including a first vertical portion and a second vertical portion facing each other in the first direction, and a horizontal portion connecting the first vertical portion and the second vertical portion;
a first word line and a second word line, both extending in the second direction across the plurality of bit lines, the first word line being disposed adjacent to the first vertical portions of the plurality of semiconductor patterns, the second word line being disposed adjacent to the second vertical portions of the plurality of semiconductor patterns, and both the first word line and the second word line being disposed on the horizontal portions of the plurality of semiconductor patterns, respectively;
a plurality of gate insulating patterns, each gate insulating pattern of the plurality of gate insulating patterns being interposed between one of the first vertical portions of the plurality of semiconductor patterns and the first word line, and between the second vertical portions of the plurality of semiconductor patterns and the second word line, and extending in the second direction across the plurality of bit lines; and
a plurality of first capping patterns, each first capping pattern of the plurality of first capping patterns being interposed between one of the plurality of gate insulating patterns and the first vertical portions; and
a plurality of second capping patterns, each second capping pattern of the plurality of second capping patterns being interposed between another one of the plurality of gate insulating patterns and the second vertical portions,
wherein each first capping pattern of the plurality of first capping patterns are spaced apart from each other in the second direction with the one of the plurality of gate insulating patterns interposed therebetween, and
wherein each second capping pattern of the plurality of second capping patterns are spaced apart from each other in the second direction with the another one of the plurality of gate insulating patterns interposed therebetween.

19. The semiconductor device of claim 18,
wherein the first vertical portions of each of the plurality of semiconductor patterns have side surfaces facing each other in the second direction,
wherein each of the plurality of first capping patterns have side surfaces facing each other in the second direction, respectively, and
wherein the side surfaces of each of the plurality of first capping patterns are aligned with the side surfaces of each of the first vertical portions along the first direction.

20. The semiconductor device of claim 18, wherein the one of the plurality of gate insulating patterns has a first thickness in the first direction between the first vertical portions of the plurality of semiconductor patterns and a second thickness in the first direction on each of the first vertical portions,
wherein each of the plurality of first capping patterns has a third thickness in the first direction between each of the first vertical portions and the one of the plurality of gate insulating patterns, and
wherein a sum of the second thickness and the third thickness is greater than the first thickness.
